(19) United States
(12) Patent Application Publication
(10) Pub. No.: US 2009/0116204 A1
(43) Pub. Date: May 7, 2009

(54) Capacitor assembly of electrical circuit system

(75) Inventors: Jake Chen, Taipei (TW); David Tsai, Taipei (TW)

Correspondence Address: BIRCH STEWART KOLASCH & BIRCH, PO BOX 747, FALLS CHURCH, VA, 22040-0747, US

(73) Assignee: Allis Electric Co., Ltd.

(21) Appl. No.: 11/979,339

(22) Filed: Nov. 1, 2007

(51) Int. Cl. H05K 1/18; H05K 3/30

(52) U.S. Cl. 361/763; 29/832

(57) ABSTRACT

This invention is about the capacitor assembly improvement of electrical circuit system, including a central partitioning board, its surface has connecting hole installed through conductive component, both sides are distributed with insertion slots; first base board installed with sleeve hole connecting to one end of conductive component and an insertion hole corresponding to the insertion slot, its one side is soldered with multiple capacitors; and second base board, having a sleeve hole connecting to the other end of the conductive component and the insertion hole corresponding to the insertion slot, one side is soldered with multiple capacitors; thus the conductive component is inserted through central partitioning board and assemble the first and second base boards to both ends of the conductive component, to replace cable layout to form electrical connectivity, so that the problem of electrical circuit system of prior art having noise and high assembly cost can be overcome.

### FIELD OF THE INVENTION

The present invention relates to the improvement of capacitor assembly of a kind of electrical circuit system, and more particularly to a kind of innovation free of electrical cable and further to remove noise as well as to reduce assembly cost.

### BACKGROUND OF THE INVENTION

The UPS is but one of the applications among widely used electrical circuit system products. The said UPS combines the functions of power supply and battery storage, which is a derived product that belongs to the ordinary power supply. It is for providing power while the power source is interrupted so as to maintain the normal operation of computer system or precision equipment that need source of power. One of the main internal components is the central partitioning board made of metallic material; the two sides of the central partitioning board are installed with an electrical circuit; the said electrical circuit board usually is a PCB; and the surface of the said PCB does not have the installation of high voltage capacitor.

Though this design there is no electrical connection between each electrical circuit board and the capacitor. The reason is that the size of the capacitor being too large and there is no way to install on the surface of each said PCB. Therefore, between the two large capacitors a electrical cable must be used in order to provide further electrical connection.

### SUMMARY OF THE INVENTION

The inventor of this innovation made further analysis on the reaction to the use in the market and discovered that between the capacitor and the PCB of the above stated electrical circuit the electrical cable must be installed in order to form electrical connection. However, the problem arises due to increase in assembly cost and resulting in large amount of noises. Hence, the structure of the capacitor of the electrical circuit system product of prior art is not sufficient and there is need for further improvement.

In view of the problem of the capacitor structure of the above stated electrical circuit system product, the inventor of this innovative product devoted unending effort in the study of improvement and finally created the improvement of the capacitor assembly of a kind of electrical system in order to perfect the capacitor structure of the electrical circuit product.

Therefore, the objective of this invention is in providing a kind of conductive component for forming electrical connectivity on two sides of the central partitioning board in order to achieve the purpose of free of installation of electrical cable, reduction of assembly cost, and reduction of noises.

To achieve the above stated objective, a kind of improvement on the capacitor assembly of the electrical circuit system is created. The method is as follows: a central partitioning board, its surface is installed with a conductive component through connecting holes, and both sides are having insertion slots; a first base board is installed with the sleeve hole for connecting to the said conductive component and insertion hole corresponding to the said insertion slot, and one side of which is soldered with multiple capacitors; and a second base board connecting to the said conductive component connecting to the other end of the sleeve hole and the insertion hole corresponding to the said insertion slot, and one side of which is also soldered with multiple capacitors.

In this way, when the circuit is realized, the first and the second base boards are align back-to-back on the two sides of the central partitioning board, the conductive component is used to go through the said central partitioning boards and the first and second base boards are assembled on the two ends of the said conductive component to form electrical connection.

### BRIEF DESCRIPTION OF THE DRAWINGS

FIG. 1 is the 3D illustration of one side of the central partitioning board of this invention.

FIG. 2 is the 3D illustration of the other side of the central partitioning board of this invention.

FIG. 3 is the 3D exploded diagram of the central partitioning board and the first and second base boards of this invention.

FIG. 4 is the top view of this invention after assembly.

### DETAILED DESCRIPTION OF THE PREFERRED EMBODIMENT

Please refer to the figures illustrating the embodiment for the detailed description of this invention as shown below:

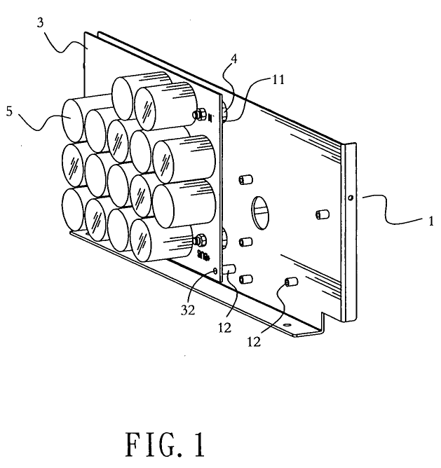

FIG. 1 shows the 3D illustration of one side of the central partitioning board of this invention, wherein the surface of the central partitioning board (1) is installed with a multiple of connecting holes (11), the said connecting hole (11) can be installed through with a conductive component (4), using one end of the said conductive component (4) to be assembled with a first base board (3), the said first base board (3) can be a PCB board and its one side is soldered with a multiple of capacitors (5).

In addition, the surface of the said central partitioning board (1) is installed with an insertion slot (12) that can form correspondence with the insertion hole (32) of the first base board (3).

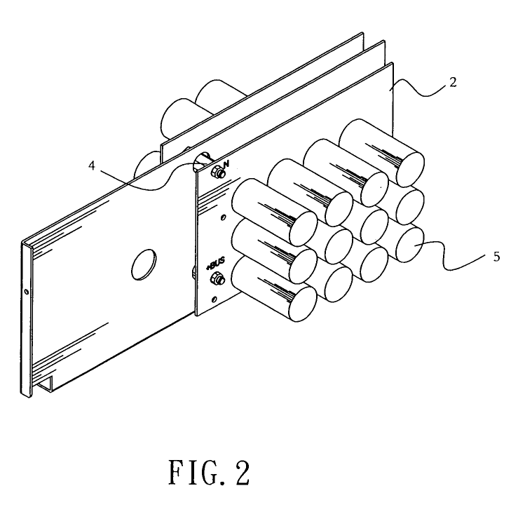

As shown in FIG. 2, which is the 3D illustration of the other side of the central partitioning board of this invention, the other end of the above stated conductive component (4) is assembled with a second base board (2), the said second base board (2) can be a PCB board and its one side is also soldered to multiple capacitors (5).

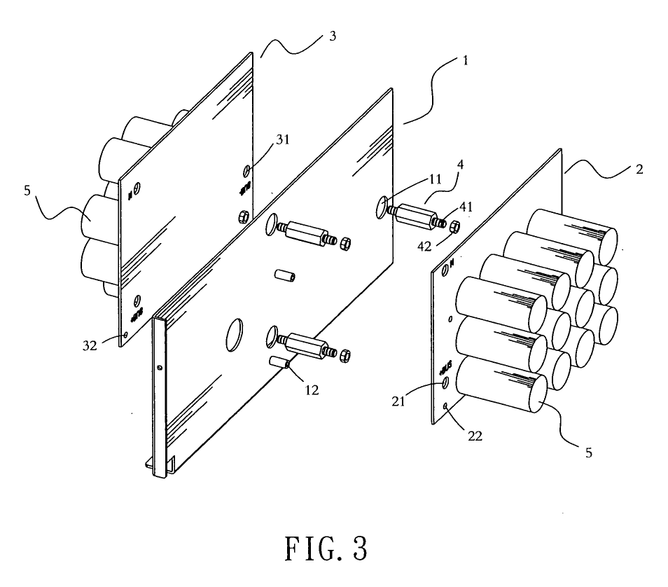

As shown in FIG. 3, which is the 3D exploded illustration of the central partitioning board and the first and the second base boards of this invention, from this figure one can understand this innovation mainly contains: a central partitioning board (1), its surface is installed with connecting holes (11) that could insert through conductive component (4), both sides are distributed with multiple insertion slots (12) (also refer to FIG. 1); a first base board (3) installed with a sleeve hole (31) connecting to one end of the said conductive component (4) and an insertion hole (32) corresponding to the said insertion slot (12) (also refer to FIG. 1), and one side of it is soldered to multiple capacitors (5); and a second base board (2), installed with a sleeve hole (21) connecting to the said conductive component (4) and an insertion hole (22) corresponding to the said insertion slot (12), and one side of which is also soldered with multiple capacitors (5);

The above stated conductive component (4) is made of conductive material, which could be electrically connected to the said first base board (3) and the said second base board (2), hence the conductive component (4) in this invention could be optionally made of metallic material, such as a hex boss;

The above stated conductive component (4), and both ends of which could be connected to the thread (41) of the nut (42), the said thread (41) itself has a suitable length, which could provide the sleeve hole (31) for the first base board (3), the sleeve hole (21) for the second base board (2) so that after insertion, the nut (42) could be used to lock in so as to form the assembly.

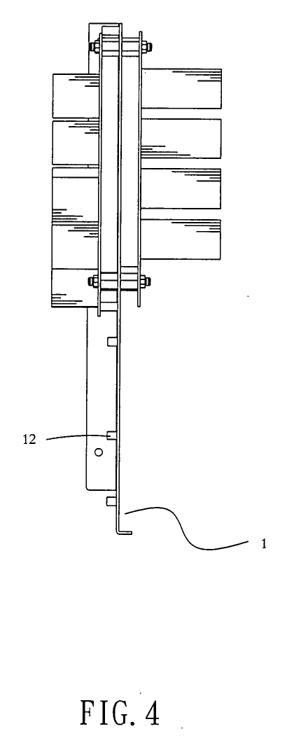

Through the structure of the above stated assembly, please refer to FIG. 1 through FIG. 4, wherein both sides of the central partitioning board (1) is assembled with the first base board (3) and the second base board (2) respectively through conductive component (4), so that between the previously stated first and second base boards (3), (2) the electrical connection is formed, at the same the capacitors (5) located on both sides of the central partitioning board (1) can also form electrical connection, as such this invention does not require massive cable layout, at the same time the problem of too high assembly cost and large amount of noise derived by the cable layout can also be overcome. As shown in FIG. 4, which is the top view of this invention after assembly. It can be seen from this figure that the surface of the central partitioning board (1) at the suitable place is still installed with multiple insertion slots (12).

In summary, comparing the capacitor structure between this invention and prior art, the conductive component is used to form electrical connection between the first and the second base boards, in order to achieve rid of cable configuration and also could have the features of lowering the assembly cost and eliminating large amount of noise, which is really improvement of functions and suitable to the requirement of application of new type of patent, hence the proposal of application of new patent.

What is claimed is:

1. A kind of capacitor assembly improvement of the stated electrical circuit system, including:
A central partitioning board, its surface has a connecting hole installed with a conductive component, and two sides are distributed with insertion slots;
A first base board, installed with the sleeve hole connecting to one end of the said conductive component corresponding to the insertion hole of the said insertion slot, and one side of the board is soldered with a multiple of capacitors; and
A second base board, with the sleeve hole connecting to the other end of the said conductive component corresponding to the insertion slot of the said insertion slot, and one side of the board is also soldered with a multiple of capacitors;

2. The capacitor assembly improvement of the stated electrical circuit system as claimed in claim 1, wherein the said conductive component is made of material with conductive quality, so as to electrically connect the said first base board and the second base board.

3. The capacitor assembly improvement of the stated electrical circuit system as claimed in claim 1, wherein the two ends of the said conductive component form threads for the connection with nuts.

4. The capacitor assembly improvement of the stated electrical circuit system as claimed in claim 1, wherein the said conductive component could be a hex boss.

5. The capacitor assembly improvement of the stated electrical circuit system as claimed in claim 1, wherein the first base board could be a PCB board.

6. The capacitor assembly improvement of the stated electrical circuit system as claimed in claim 1, wherein the second base board could be a PCB board.
